(19) United States
(12) Patent Application Publication
(10) Pub. No.: US 2023/0350303 A1
(43) Pub. Date: Nov. 2, 2023

(54) Dry Developing Metal-Free Photoresists

(71) Applicant: Tokyo Electron Limited, Tokyo (JP)

(72) Inventors: Charlotte Cutler, Albany, NY (US); David Conklin, Albany, NY (US)

(21) Appl. No.: 18/193,324

(22) Filed: Mar. 30, 2023

Related U.S. Application Data
(60) Provisional application No. 63/335,525, filed on Apr. 27, 2022.

(51) Int. Cl. G03F 7/20; G03F 7/00; G03F 7/075; G03F 7/031; G03F 7/16

(52) U.S. Cl. CPC G03F 7/2002; G03F 7/70033; G03F 7/70975; G03F 7/0752; G03F 7/031; G03F 7/162

(57) ABSTRACT

A method of patterning an underlying layer that includes: depositing a metal-free polymer film over the underlying layer, exposing the film to an EUV to form an exposed region and a masked region of the film, the exposed region photoreacting to the EUV; selectively dry etching first portions of the film to form features including the remaining second portions of the film, an etch rate of the first portions being greater than that of the second portions of the film, the first portions being one of the exposed region and the masked region, the second portions being another of the exposed region and the masked region that is not the first portion, where a pitch of the features is below the feature size achievable with a 193 nm immersion lithography tool in a single patterning process; and patterning the underlying layer using the second portion as an etch mask.

### CROSS-REFERENCE TO RELATED APPLICATIONS

This application claims the benefit of U.S. Provisional Application No. 63/335,525, filed on Apr. 27, 2022 which application is hereby incorporated herein by reference.

### TECHNICAL FIELD

The present invention relates generally to a method of processing a substrate, and, in particular embodiments, to dry developing of metal-free photoresists.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. Developing refers to selective removal of a reacted or unreacted region of the photoresist material. The relief pattern then may be transferred to a target layer below the photoresist or an underlying hard mask layer formed over the target layer. Innovations in patterning such as immersion photolithography, multiple patterning, and 13.5 nm wavelength extreme ultraviolet (EUV) optical systems have brought critical feature sizes down close to ten nanometers. Concurrently, these advanced photolithographic techniques and systems demand development of new materials and process flows to satisfy the cost and quality requirements for patterning at nanoscale features.

### SUMMARY

In accordance with an embodiment of the present invention, a method of patterning an underlying layer that includes: providing a substrate including the underlying layer; depositing a metal-free polymer film over the underlying layer, exposing the metal-free polymer film to an extreme ultraviolet (EUV) irradiation through a photomask to form an exposed region of the metal-free polymer film and a masked region of the metal-free polymer film, the exposed region photoreacting in response to the EUV irradiation; loading the substrate into a processing chamber; selectively dry etching first portions of the metal-free polymer film using an etch gas in the processing chamber to form a plurality of features including the remaining second portions of the metal-free polymer film, an etch rate of the first portions being greater than an etch rate of the second portions of the metal-free polymer film, the first portions being one of the exposed region and the masked region, the second portions being another of the exposed region and the masked region that is not the first portion, where a pitch of the plurality of features is below the feature size achievable with a 193 nm immersion lithography tool in a single patterning process; and patterning the underlying layer disposed under the metal-free polymer film using the second portion as an etch mask.

In accordance with an embodiment of the present invention, a method of patterning an underlying layer that includes: depositing a metal-free polymer film over a substrate by a spin-on process, the metal-free polymer film including a carboxyl group, the substrate including the underlying layer; decarboxylating a portion of the metal-free polymer film by exposing the substrate to an extreme ultraviolet (EUV) irradiation through a photomask, the portion of the metal-free polymer film being a region exposed to the EUV irradiation, the decarboxylating including a photoreaction in response to the EUV irradiation; loading the substrate into a processing chamber; exposing the substrate to a plasma to selectively remove a region that is masked by the photomask and not exposed to the EUV irradiation, the plasma being generated in the processing chamber, where an etch rate of the masked region is greater than an etch rate of the exposed region by at least a factor of 2; and patterning the underlying layer disposed under the metal-free polymer film using the exposed region as an etch mask.

In accordance with an embodiment of the present invention, a method of patterning an underlying layer that includes: depositing a metal-free polymer film over a substrate including an underlying layer by a spin-on process; oxidizing a portion of the metal-free polymer film by exposing the substrate to an extreme ultraviolet (EUV) irradiation through a photomask, the oxidizing including a photoreaction in response to the EUV irradiation; loading the substrate into a processing chamber; exposing the substrate to a plasma to selectively remove the exposed region, the plasma being generated in the processing chamber, where an etch rate of the exposed region is greater than an etch rate of a region that is masked by the photomask and not exposed to the EUV irradiation by at least a factor of 2; and patterning the underlying layer disposed under the metal-free polymer film using the masked region as an etch mask.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1F illustrate schematic views of an example substrate at various stages during an example process of fabrication comprising a dry develop step of a metal-free polymer film in accordance with various embodiments, wherein FIG. 1A illustrates a cross-sectional view of the incoming substrate, FIG. 1B illustrates a cross-sectional view of the substrate after depositing the metal-free polymer film, FIG. 1C illustrates a cross-sectional view of the substrate after performing extreme ultraviolet (EUV) exposure through a photomask, FIG. 1D illustrates a cross-sectional view of the substrate after dry developing the metal-free polymer film to remove the masked region of the metal-free polymer film, FIG. 1E illustrates a cross-sectional view of the substrate after performing a first pattern transfer etch, and FIG. 1F illustrates a cross-sectional view of the substrate after performing a second pattern transfer etch;

FIG. 2A illustrates a cross-sectional view of the substrate during the dry develop step of the metal-free polymer film that comprises an area selective deposition in accordance with other embodiments;

FIG. 2B illustrates a cross-sectional view of the substrate after completing the dry develop step of the metal-free polymer film in accordance with the embodiments of FIG. 2A;

FIG. 3 illustrates a cross-sectional view of another example substrate after a conventional wet develop step with pattern collapse issues;

FIG. 4A-4E illustrate schematic views of an alternate example substrate at various stages during an example process of fabrication comprising a dry develop step of a metal-free polymer film in accordance with other embodiments, wherein FIG. 4A illustrates a cross-sectional view of the substrate after depositing the metal-free polymer film, FIG. 4B illustrates a cross-sectional view of the substrate after performing extreme ultraviolet (EUV) exposure through a photomask, FIG. 4C illustrates a cross-sectional view of the substrate after dry developing the metal-free polymer film to remove the exposed region of the metal-free polymer film, FIG. 4D illustrates a cross-sectional view of the substrate after performing a first pattern transfer etch, and FIG. 4E illustrates a cross-sectional view of the substrate after performing a second pattern transfer etch;

FIG. 5 illustrates a schematic of the relationship between Ohnishi parameter (OP) of polymer and dry etch rate thereof;

FIG. 6 illustrates an example mechanism of decarboxylation that can reduce the OP of the metal-free polymer film comprising a carboxyl group in response to the EUV exposure;

FIG. 7 illustrates schematic views of the metal-free polymer film undergoing a structural change via crosslinking in response to the EUV exposure;

FIG. 8 illustrates schematic views of the metal-free polymer film undergoing a structural change via chain scission in response to the EUV exposure;

FIGS. 9A-9C illustrate example process flow diagrams of the fabrication process comprising the dry develop of the metal-free polymer film, wherein FIG. 9A illustrates an embodiment, FIG. 9B illustrates an alternate embodiment, and FIG. 9C illustrates yet another embodiment; and

FIG. 10 illustrates an example plasma processing tool in accordance with an embodiment of this disclosure.

### DETAILED DESCRIPTION OF ILLUSTRATIVE EMBODIMENTS

This application relates to a method of processing a substrate, more particularly to dry developing a metal-free polymer film. A common developing technique for a photoresist widely used in industry is wet develop, where a substrate is treated with a developing solution to dissolve only the reacted or unreacted region of the photoresist. While wet develop is highly effective for conventional UV lithographic optical systems and techniques, as the feature size continues to shrink, wet develop is unable to satisfactorily develop at least in part due to pattern collapse during wet develop. Especially with an extreme ultraviolet (EUV) optical system that is being introduced at the sub-10 nm technology nodes, such issues inherent in photoresist and develop method become more critical than the optical resolution limit. To date, new types of photoresist based on metal and/or metal oxide for EUV patterning have been disclosed, for example, by Inpria (e.g., US Patent Application Publication US 2020/0064733 A1, Meyers et al.; US Patent Application Publication US 2019/0308998 A1, Cardineau et al.) and Lam Research (US Patent Application Publication US 2021/0265163 A1, Yu et al.; US Patent Application Publication US 2017/0146909 A1, Smith et al.). In certain fabrication processes such as front-end-of-line (FEOL), metal contamination has to be strictly avoided. Therefore, new EUV photoresist materials and their develop techniques may be desired. Embodiments of the present application disclose methods of EUV patterning using a metal-free polymer film as a photoresist and dry develop of the metal-free polymer film to obtain features obtainable with EUV lithography.

The methods described in this disclosure may advantageously improve process performance by preventing pattern collapse during develop and enhancing throughput. Other advantages may include eliminating the need of developing solutions. The dry develop in various embodiments may be enabled by changing the Ohnishi parameter of the metal-free polymer film and consequently the dry etch rate thereof, in contrast to the solubility change in case of conventional wet develop. Accordingly, new polymer-based, metal-free EUV photoresist may be developed based on the embodiments. The methods in various embodiments may also comprise area selective deposition (ASD) as a part of the dry develop step, which improves the etch selectivity among the regions of the metal-free polymer film and thereby the tonality thereof as the metal-free EUV photoresist. While the description in this disclosure primarily references EUV as the photoresist irradiation source, other forms of radiation (e.g., deep UV, X-ray, or e-beam) may also be contemplated in other embodiments.

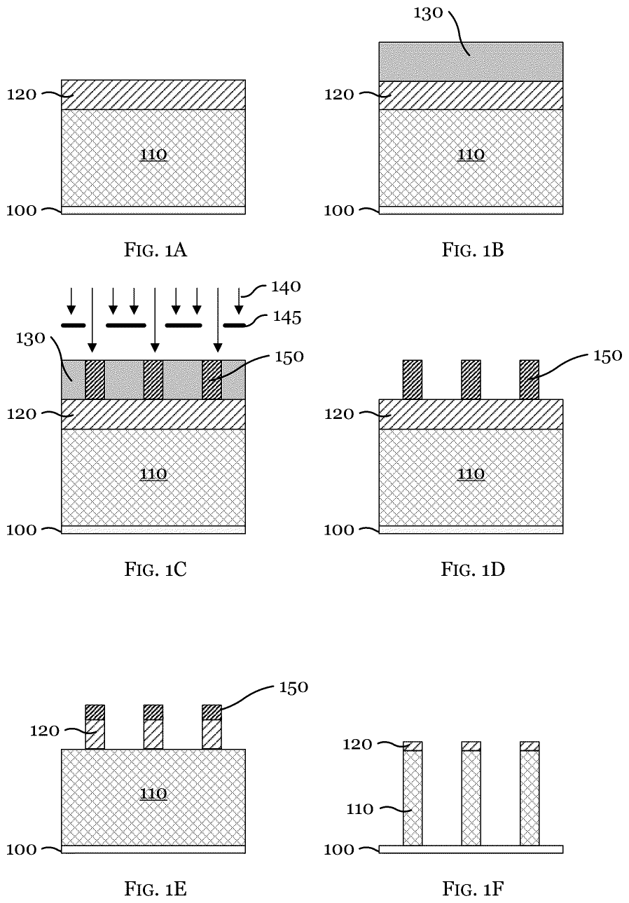

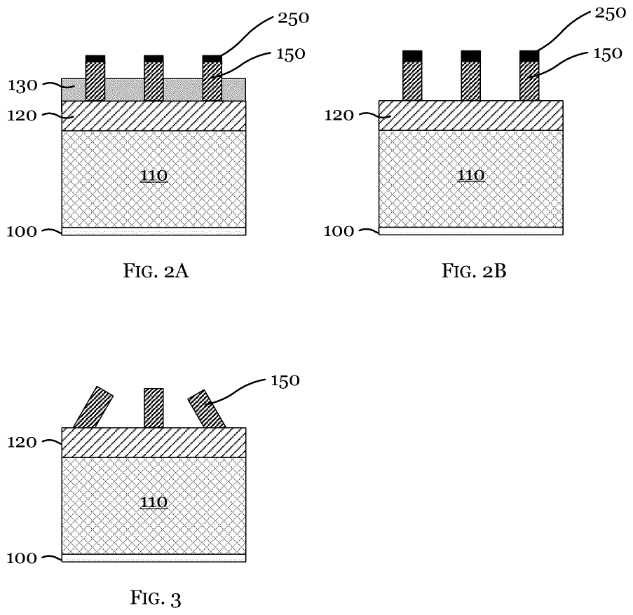

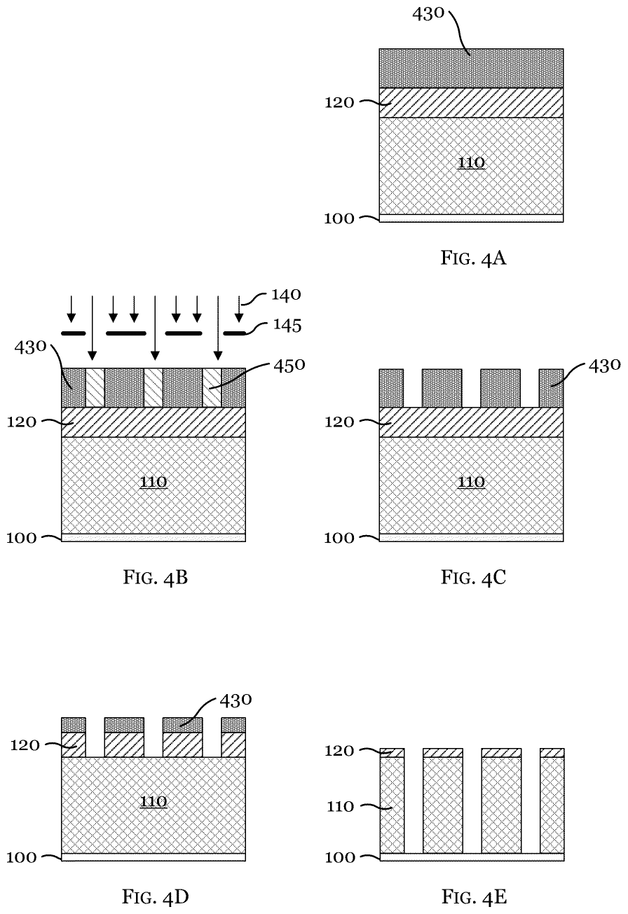

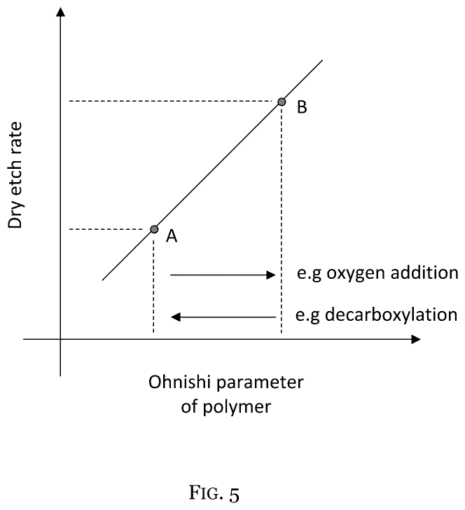

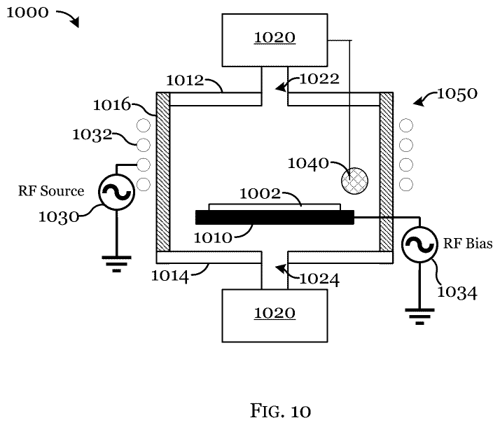

In the following, the methods of EUV patterning using the metal-free polymer film is first described referring to FIGS. 1A-1D in accordance with various embodiments with an example of a negative tone photoresist. In particular, a dry develop step is described in FIG. 1D along with FIGS. 2-3. Embodiments that comprise ASD during the dry develop step to enhance the tonality are described referring to FIGS. 2A and 2B. In FIG. 3, the pattern collapse issue from a conventional wet develop process is described for comparison. Example subsequent steps after the dry develop are illustrated in FIGS. 1E and F. Patterning in case of a positive tone photoresist is subsequently described referring to FIGS. 4A-4E. In FIG. 5, the Ohnishi parameter is introduced as a parameter that empirically predicts the dry etch rate of the metal-free polymer film. Next, examples of possible structural changes in metal-free polymer film that influence the dry etch rate are provided in FIGS. 6-8. Example process flow diagrams are illustrated in FIG. 9A-9C. FIG. 10 provides an example system for the dry develop of the metal-free polymer film. All figures in this disclosure are drawn for illustration purpose only and not to scale, including the aspect ratios of features.

FIGS. 1A-1F illustrate schematic views of an example substrate 100 at various stages during an example process of fabrication comprising a dry develop step of a metal-free polymer film as a negative photoresist in accordance with various embodiments. FIG. 1A illustrates a cross-sectional view of the incoming substrate 100.

In various embodiments, the substrate 100 may be a part of, or include, a semiconductor device, and may have undergone a number of steps of processing following, for example, a conventional process. The substrate 100 accordingly may comprise layers of semiconductors useful in various microelectronics. For example, the semiconductor structure may comprise the substrate 100 in which various device regions are formed.

In one or more embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device.

In FIG. 1A, the substrate 100 comprises an underlying layer 110 and a hard mask (HM) layer 120. The structure illustrated in FIG. 1A is for example and other suitable structures are also possible in other embodiments. In various embodiments, the underlying layer 110 may be a layer to be patterned by an EUV lithographic process. The underlying layer 110 may comprise an oxide, amorphous silicon, polysilicon, or other dielectric materials useful in semiconductor fabrication. The oxide may include carbon, hydrogen, and nitrogen in various embodiments. In some embodiments, the underlying layer 110 may comprise silicon oxide that may be prepared, for example, by plasma-enhanced CVD or flowable CVD using tetraethyl orthosilicate (TEOS) as a precursor.

The hard mask (HM) layer 120 may comprise a metal hard mask layer such as titanium nitride, titanium oxide, and hafnium oxide among others. The HM layer 120 may be deposited using deposition techniques such as vapor deposition including chemical vapor deposition (CVD), physical vapor deposition (PVD), and atomic layer deposition (ALD), as well as other plasma processes such as plasma enhanced CVD (PECVD), sputtering, and other processes.

FIG. 1B illustrates a cross-sectional view of the substrate 100 after depositing a metal-free polymer film 130.

In various embodiments, the metal-free polymer film 130 may be deposited over the HM layer 120 using a dry process or wet process, for example, a spin-coating technique. In one or more embodiments using the spin-coating technique, the metal-free polymer film 130 or precursors thereof may be dissolved in a solvent to prepare a photoresist solution, which is then dispensed from a nozzle to a central portion of the substrate 100. The photoresist solution onto the wafer may be dispensed either while the wafer is spun (i.e., dynamic dispense) or not (i.e., static dispense). The wafer is spun at a rate, for example, between 500 rpm and 4000 rpm, to exert a centrifugal force, which causes the photoresist solution to spread outwards and towards the edge of the substrate 100. As the solvent evaporates from the photoresist solution, the photoresist film may be formed over the substrate 100, coating the surface of the substrate 100 uniformly. In one embodiment, the metal-free polymer film 130 has a thickness between 10 nm and 100 nm.

The process conditions for the spin-coating technique may comprise spin speed, spin time, solvent system, and temperature among others. In certain embodiments, after the spin-coating, non-uniform features of the metal-free polymer film 130 at the edge portion (e.g., edge bead) of the substrate 100 may be formed. These non-uniform features may be removed by a conventional edge bead removal (EBR) process, in which a solvent may be dispensed to the edge portion while spinning the substrate 100.

In certain embodiments, a soft bake may optionally be performed to thermally treat the substrate 100 to remove residual solvents from the metal-free polymer film 130. The soft bake process may comprise heating the metal-free polymer film 130 within a temperature range, e.g., between 75° C. and 100° C.

In further embodiments, an optional chemical treatment step may also be inserted after the deposition of the metal-free polymer film 130 and before EUV exposure. The optional chemical treatment may introduce functional groups (e.g., a carboxyl group) that may enable or enhance the reactivity of the metal-free polymer film 130 in response to EUV exposure.

The metal-free polymer film 130 may be used as a photoresist to form a relief pattern by EUV lithography as further described below in FIGS. 1C-1F. In various embodiments, “metal free” characteristic of the metal-free polymer film 130 indicates the absence of a metal in the polymer repeat unit. The absence of the metal may benefit the application of the metal-free polymer film 130 as a EUV photoresist in a fabrication step where a metal contamination is strictly prohibited.

In various embodiments, the metal-free polymer film 130 may comprise less than the detection limit of metals in a polymer film. The detection limit of metals may be based on a conventional analytical technique to determine metal content, for example, inductively coupled plasma optical emission spectroscopy (ICP-OES). In one or more embodiments, the metal-free polymer film 130 may comprise less than 100 ppm of metals, and in some embodiments less than 1 ppm in concentration. In one or more embodiments, the content of failure critical metals such as calcium, cobalt, chromium, copper, iron, potassium, iron, manganese, molybdenum, sodium, and nickel in the metal-free polymer film 130 may be less than the less critical metals such as tungsten, hafnium, aluminum, and titanium. In one or more embodiments, the metal-free polymer film 130 may comprise silicon.

In various embodiments, the metal-free polymer film 130 may comprise a photoreactive polymer that changes the dry etch rate upon EUV exposure. The metal-free polymer film 130 may be a chemically amplified resist (CAR), in which an additional polymer or non-polymer photoreactive component is included to amplify the structural change in the metal-free polymer film (e.g., photoacid generator). Possible photo-induced chemistries for the metal-free polymer film 130 that enables EUV lithography in various embodiments are described further referring to FIGS. 5-8.

FIG. 1C illustrates a cross-sectional view of the substrate 100 after performing extreme ultraviolet (EUV) exposure through a photomask 145.

In FIG. 1C, an EUV lithographic process is performed by exposing the substrate 100 to an EUV radiation 140 through the photomask 145. With the photomask 145, only an unmasked region of the substrate 100 is irradiated with the UV radiation 140. In the illustrated example, the metal-free polymer film functions as a negative tone photoresist. Accordingly, directly or indirectly in response to the EUV exposure, the exposed region of the metal-free polymer film 130 is converted to a reacted polymer film 150. On the other hand, a masked region of the metal-free polymer film 130 remains unreacted. The reacted polymer film 150 may have undergone a structural change that leads to a change in dry etch rate, which can be utilized in a subsequent dry develop step. In various embodiments, such a structural change from the metal-free polymer film 130 to the reacted polymer film 150 may comprise, for example, decarboxylation, cyclization, or crosslinking.

In certain embodiments, after the EUV exposure, a post-exposure bake (PEB) may optionally be performed by thermally treating the substrate 100. The PEB may be beneficial in ensuring residual solvent removal and/or further differentiating the material properties of the reacted polymer film 150 from that of the metal-free polymer film 130. In one or more embodiments, the PEB may be performed at 80-220° C.

FIG. 1D illustrates a cross-sectional view of the substrate 100 after dry developing the metal-free polymer film 130 to remove the reacted polymer film 150.

Dry develop in this disclosure refers to any develop process where the selective removal of photoresist is driven by an exposure to reactive gases and/or plasma (i.e., dry etch) without involving a solvent (i.e., wet develop). The dry develop step may comprise, for example, a selective plasma etch process, purely chemical process or a thermal process, advantageously eliminating the use of a developing solution. In certain embodiments, the dry develop step may be reactive ion etching (RIE) or atomic layer etching (ALE). In one or more embodiments, an etch gas for the dry develop step may comprise a mixture of H₂ and CO. In other embodiments, the etch gas may comprise halogen (e.g., HBr, HCl, or HI), oxygen (e.g., O₂), and/or sulfur (e.g., SO₂ or SF₆). In certain embodiments, for example, when using ALE for the dry develop step, a cyclic process may be performed. The etch gas composition and process conditions of the dry develop step may be selected to maximize the dry etch selectivity, for example, to the metal-free polymer film 130 in the illustrated example of the negative tone photoresist. As a result, in FIG. 1D, the reacted polymer film 150 remains after the dry develop step and the unreacted region of the metal-free polymer film 130 is removed. In one embodiment, the etch rate of the reacted polymer film 150 is greater than the etch rate of the masked (unreacted) region of the metal-free polymer film 130 by at least a factor of 2. In certain embodiments, area selective deposition (ASD) may be accompanying the etching of the dry develop step. The ASD may be utilized because the EUV exposure as described above in FIG. 1C results in two regions of polymer with different compositions (i.e., the metal-free polymer film 130 and the reacted polymer film 150). The ASD over the metal-free polymer film 130 may advantageously enhance or invert the inherent tonality of the metal-free polymer film 130.

FIG. 2A illustrates a cross-sectional view of the substrate 100 during the dry develop step of the metal-free polymer film 130 that comprises an area selective deposition (ASD) in accordance with various embodiments.

FIG. 2B illustrates a cross-sectional view of the substrate 100 after completing the dry develop step of the metal-free polymer film 130 in accordance with the embodiments of FIG. 2A.

The performance of a dry develop photoresist may be improved by increasing the dry etch selectivity. In accordance with an embodiment, one method to increase the dry etch selectivity is to utilize ASD during etching the metal-free polymer film. As illustrated in FIG. 2A, a material 250, for example, comprising a carbonaceous material, may be selectively deposited over the reacted polymer film 150 while dry etching the metal-free polymer film 130 using an etch gas comprising carbon. The inventors of this application identified that such ASD may be enabled by controlling the C/O and/or H/C ratio of the etch gas. In one embodiment, the material 250 comprising carbon may selectively deposited over a carbon-rich polymer (e.g., polystyrene-based) while etching a carbon-deficient polymer (e.g., polymethyl methacrylate-based). Such ASD may be enabled and enhanced by reducing the H/C ratio of the etch gas. As illustrated in FIG. 2B, after completing the selective removal of the metal-free polymer film 130, the reacted polymer film 150 is reinforced by the addition of the material 250. The material 250 on top of the polymer film 150 may function as an extra layer of etch mask during a subsequent pattern transfer etch.

In alternate embodiments, area selective deposition (ASD) of the material 250 may be achieved step wise by performing a deposition step separated from the selective etching illustrated in FIG. 1D. In other words, the dry develop process may comprise a series of process steps. For example, after the EUV exposure (e.g., FIG. 1C), a deposition gas may be introduced to a processing chamber to selectively deposit the material 250 over the reacted polymer film 150 without substantially affecting the metal-free polymer film 130. Once a sufficient amount of the material 250 is deposited, an etch gas may be introduced to the processing chamber to selectively etch the metal-free polymer film 130. In certain embodiments, the deposition gas and the etch gas may comprise similar gas mixtures (e.g., H₂ and CO) and switching from the ASD to selective etch may be achieved by changing the mixing ratio of the gas mixtures or other process conditions such as bias power, temperature, and pressure.

FIG. 3 illustrates a cross-sectional view of another example substrate 100 after a conventional wet develop step with pattern collapse issues.

Compared with the dry develop step as described above, a wet develop step is a solution-based process using a developing solution that selectively dissolves either a reacted region or unreacted region of the photoresist. While wet develop is predominantly used industry, as the feature patterned by lithography becomes to have a smaller pitch and a high aspect ratio, it suffers issues such as pattern collapse as illustrated in FIG. 3. Pattern collapse may occur due to surface tension caused by the developing solution and/or delamination during the wet develop step. Generally, EUV lithography may be used to form small features not readily achievable by other lithography techniques such as 193 nm immersion lithography. For example, while the minimum pitch for a resist line-and-space pattern formed using 193 nm immersion lithography is about 75 nm, the shorter 13.5 nm EUV lithography enables the minimum pitch about 20 nm to about 40 nm.

The dry develop of the metal-free polymer film 130 enabled in various embodiments can advantageously overcome the issue of pattern collapse at such scales of features patterned by EUV lithography. The dry develop step may be achieved by selectively dry etching portions of the metal-free polymer film 130 using an etch gas in a processing chamber to form features comprising the remaining portions of the metal-free polymer film 130. In certain embodiments, a pitch of the features after the dry develop is close to or below the feature size achievable with a 193 nm immersion lithography tool in a single patterning process. For example, using an EUV lithographic tool using 13.5 nm EUV at numerical aperture (NA) of 0.33, the resolution limit may be as small as 22.5 nm, corresponding to k, factor of 0.5. The resolution limit may be a half-pitch size of the features in various embodiments. Furthermore, the dry develop method of this disclosure may be particularly advantageous in a high-NA (e.g., 0.5) system that improves the resolution limit. In one or embodiments, the pitch of the features achievable without pattern collapse may be between 10 nm and 80 nm. Avoiding a solution-based process also benefits in reducing chemical wastes as well as improves the process efficiency by enabling develop to be performed in the same processing chamber as a subsequent pattern transfer etch.

FIG. 1E illustrates a cross-sectional view of the substrate 100 after performing a first pattern transfer etch.

FIG. 1F illustrates a cross-sectional view of the substrate 100 after performing a second pattern transfer etch.

Referring back to FIGS. 1E and 1F, a subsequent process of EUV patterning after the dry develop step (e.g., FIG. 1D or 2B) may be performed. In various embodiments, the subsequent process is a part of the fabrication process for semiconductor device such as front-end-of-line (FEOL). In certain embodiments, this stage of the fabrication may be required to be strictly free from metal contamination. Because previously known dry develop techniques are designed for metal-oxide based photoresists and may be difficult to be implemented in such fabrication processes with strict restrictions, applying the methods of dry develop of metal-free polymer film can be advantageous.

In FIG. 1E, the pattern of the reacted polymer film 150 may be first transferred to the hard mask (HM) layer 120 by a selective etch, for example, using reactive ion etching (RIE). During this first pattern transfer etch, the reacted polymer film 150 functions as an etch mask. After the first pattern transfer etch, the reacted polymer film 150 may be consumed partially or completely. Similarly, a second pattern transfer etch may follow in certain embodiments, where the pattern of the HM layer 120 is further transferred to the underlying layer 110, for example, using reactive ion etching (RIE). In various embodiments, the dry develop step, the first pattern transfer etch, and the second pattern transfer etch may advantageously be performed in the same processing chamber. The area selective deposition (ASD) to enhance the dry etch selectivity may be incorporated in any of these three steps and/or separately inserted in between.

FIG. 4A-4E illustrate schematic views of an alternate example substrate 100 at various stages during an example process of fabrication comprising a dry develop step of a metal-free polymer film 430 as a positive photoresist in accordance with other embodiments. Details of the structure of the substrate 100 and the process of fabrication, including optional processes such as area selective deposition (ASD), soft bake, and post-exposure bake (PEB), are same as the prior embodiments illustrated in FIGS. 1A-1F (embodiments of a negative photoresist) except the tonality of the metal-free polymer film 430, and therefore not repeated.

FIG. 4A illustrates a cross-sectional view of the substrate 100 after depositing the metal-free polymer film 430.

FIG. 4B illustrates a cross-sectional view of the substrate 100 after performing extreme ultraviolet (EUV) exposure through a photomask 145.

In FIG. 4A, the metal-free polymer film 430 may be deposited by, for example, a spin-coating technique. In FIG. 4B, an EUV lithographic process is performed by exposing the substrate 100 to an EUV radiation 140 through the photomask 145. In the illustrated example of the positive tone photoresist, directly or indirectly in response to the EUV exposure, the exposed region of the metal-free polymer film 430 is converted to a reacted polymer film 450. In various embodiments, a structural change from the metal-free polymer film 130 to the reacted polymer film 450 may comprise, for example, addition of oxygen (oxidation), ring opening, or chain scission.

FIG. 4C illustrates a cross-sectional view of the substrate 100 after dry developing the metal-free polymer film 430 to remove the masked region of the metal-free polymer film 430.

In certain embodiments, the dry develop step may be reactive ion etching (RIE) or atomic layer etching (ALE). The etch gas composition and process conditions of the dry develop step may be selected to maximize the dry etch selectivity, for example, to the reacted polymer film 450 in the illustrated example of the positive tone photoresist. As a result, in FIG. 4C, the unreacted region of the metal-free polymer film 430 remains after the dry develop step and the reacted polymer film 450 is removed. In one embodiments, the etch rate of the reacted polymer film 450 is less than the etch rate of the masked (unreacted) region of the metal-free polymer film 430 by at least a factor of 2.

FIG. 4D illustrates a cross-sectional view of the substrate 100 after performing a first pattern transfer etch.

FIG. 4E illustrates a cross-sectional view of the substrate 100 after performing a second pattern transfer etch.

In FIG. 4D, the pattern of the unreacted metal-free polymer fil 430 may be first transferred to the hard mask (HM) layer 120 by a selective etch, for example, using reactive ion etching (RIE). Similarly, a second pattern transfer etch may follow in certain embodiments, where the pattern of the HM layer 120 is further transferred to the underlying layer 110, for example, using reactive ion etching (RIE).

FIG. 5 illustrates a schematic of the relationship between Ohnishi parameter (OP) of polymer and dry etch rate thereof.

The effectiveness of the metal-free polymer film as a photoresist primarily depends on the change in dry etch rate caused by the lithographic exposure. Therefore, when designing the metal-free polymer film, it is useful to know how photo-induced structural change of polymer may be correlated to the dry etch rate. Ohnishi parameter (OP), or Ohnishi number, is a useful parameter in this regard. The OP of a polymer is defined as the number of atoms in the polymer repeat unit (i.e., monomer unit) divided by the number of carbon atoms minus the number of oxygen atoms. Accordingly, the more carbon rich the polymer is, the lower the corresponding OP is. The polymer with high aromaticity and ring structure also makes the OP smaller than that with low aromaticity with no ring structure. It has been empirically known that an etch rate of a polymer by reactive ion etching (RIE) is linearly proportional to the OP of the polymer as illustrated in FIG. 5. Calculating the OP for different polymer compositions, it is possible to generally predict the dry etch rate from the chemical structure of the polymer repeat unit. For example, two polymer compositions A (carbon-rich) and B (carbon-deficient) may be considered in FIG. 5. The composition A, having a lower OP than the composition B, should exhibit a slower dry etch rate. This difference may be utilized to enable the tonality of a polymer as a photoresist when the lithographic exposure can induce the structural change from the composition A to B or vice versa. Accordingly, the metal-free polymer film in various embodiments may comprise a polymer that may change its OP in response to the EUV exposure. In certain embodiments, the change of metal-free polymer film in OP caused by the EUV exposure may be at least a factor of 2. Although OP is derived from the chemical structure of the polymer repeat unit, this does not limit the polymer for the metal-free polymer film to have only one type of monomer. In various embodiments, the polymer for the metal-free polymer film may be formed from more than one type of monomer (e.g., copolymer from two types of monomer and terpolymer from three types of monomer). In certain embodiments, an average OP may be conceived for such a polymer system and a similar design approach may be applied.

In various embodiments, the metal-free polymer film may comprise oxygen, and some oxygen of the metal-free polymer film may be removed in response to the EUV exposure, resulting in the reacted polymer film having a reduced OP from the initial OP. This makes the metal-free polymer film a negative photoresist. In certain embodiments, the oxygen removal may be realized via decarboxylation when the metal-free polymer film comprises a carboxyl group. In one embodiment, each of the polymer repeat units may comprise a carboxyl group. In other embodiments, the metal-free polymer film may comprise carbohydrate and the oxygen removal may proceed via deoxygenation. On the other hand, if an oxygen atom is added to the metal-free polymer film through, for example, oxidation, the OP increases, enabling a positive photoresist.

In further embodiments, the metal-free polymer film may undergo cyclization to form a ring structure, for example, via a Diels Alder reaction in response to the EVU exposure. The cyclization may also reduce the OP, benefiting in the negative tonality. Conversely, a ring opening of the metal-free polymer film comprising a ring structure may enable a positive photoresist by increasing the OP.

FIG. 6 illustrates an example mechanism of decarboxylation that can reduce the Ohnishi parameter (OP) of the metal-free polymer film comprising a carboxyl group in response to an UV exposure.

In FIG. 6, only a polymer repeat unit of the metal-free polymer film is described for illustration purpose. In various embodiments, decarboxylation of the metal-free polymer film may or may not require a catalyst for the reaction. In this illustrated example of photooxidant-catalyzed decarboxylation, the carboxyl group of the polymer repeat unit forms a carboxylate anion (ROO⁻) in a basic condition, which can donate an electron to a catalyst, a photooxidant that is excited by the UV exposure (e.g., a phenanthrene cation), forming a reactive carboxyl radical (RCOO·). This radical then undergoes a dissociation to form R· by releasing CO₂. In other embodiments, decarboxylation may proceed with a different mechanism.

In further embodiments, chemical reactions that do not necessarily involve a change in Ohnishi parameter (OP) (i.e., without altering the polymer repeat unit) may also be utilized for enabling the tonality of the metal-free polymer film as a photoresist. Examples of such reactions include crosslinking and chain scission. In various embodiments, the change in OP may advantageously be accompanied by other mechanisms such as crosslinking/chain scission to further enhance the tonality of the metal-free polymer film. Formation or removal of cage functionality may also be utilized. Such mechanisms may further comprise reacting a functional group comprising silicon, phosphorous, fluorine, or sulfur among others, which may provide high dry etch resistance. In one embodiment, a sulfur functional group may be removed by releasing SO₂. In addition, the formation of micro/mesopores and/or the increase in free volume in the metal-free polymer film as a result of a photoreaction may also be another facto to affect the totality through the change in etch rate.

Furthermore, a change in the glass transition temperature (T_{g}) may also be utilized to influence the dry etch selectivity. Although not wishing to be limited by any theory, generally a dry etch rate of a polymer may increase with increasing process temperature, and the effect of process temperature on the etch rate may be prominent around at a T_{g} of the polymer material or higher. Therefore, any reactions that may lower the T_{g} of the metal-free polymer film may increase its etch rate. On the other hand, increasing the T_{g} of the metal-free polymer film may decrease the etch rate. One example of the reactions to lower the T_{g} is the formation of a carboxylic acid, for example, performed as a deprotection step. Decarboxylation, on the other hand, is an example of the reactions to increase the T_{g}.

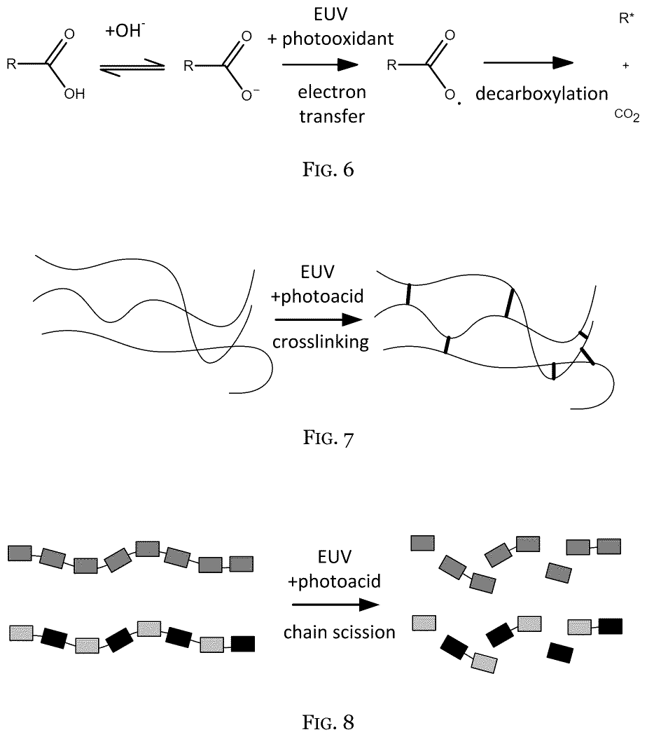

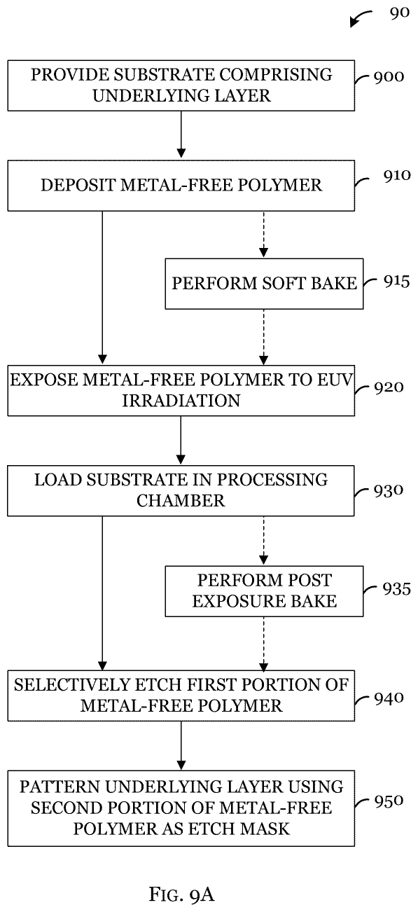

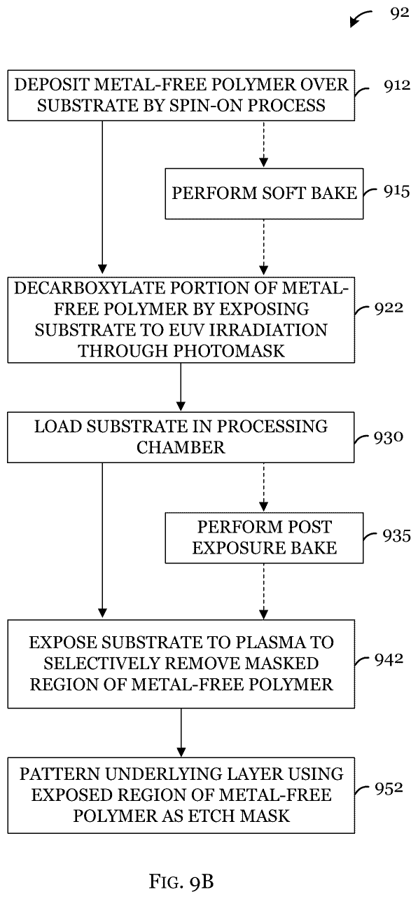

FIG. 7 illustrates schematic views of the metal-free polymer film undergoing a structural change via crosslinking in response to the EUV exposure.

In FIG. 7, polymer chains comprising the metal-free polymer film are cross-linked via bond formation induced by the EUV exposure. In certain embodiments, the crosslinking may comprise C—C bond formation or S—S bond formation among others. Such bond formations may be catalyzed by a photoacid generated by the EUV exposure. In one embodiment, the metal-free polymer film may comprise hydroxystyrene that may undergo crosslinking by the EUV exposure. Although crosslinking may not substantially change the Ohnishi parameter (OP), the crosslinked polymer exhibits an improved dry etch resistance and may benefit in the negative tonality.

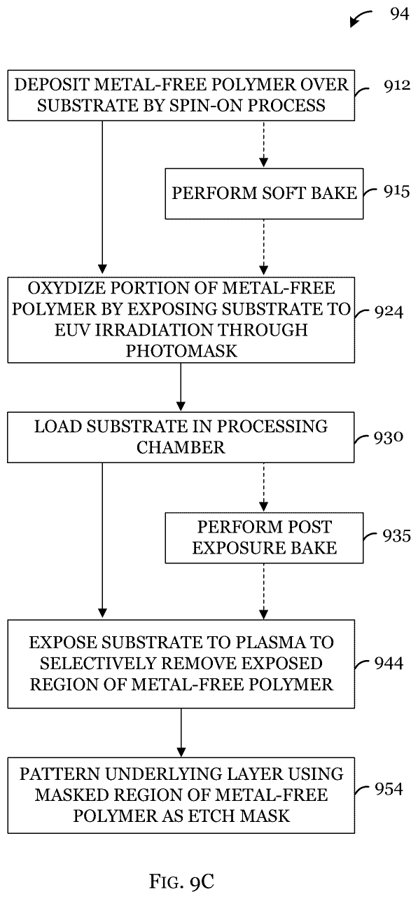

FIG. 8 illustrates schematic views of the metal-free polymer film undergoing a structural change via chain scission in response to the EUV exposure.

In FIG. 8, polymer chains comprising the metal-free polymer film are fragmented via chain scission induced by the EUV exposure. In certain embodiments, the metal-free polymer film may comprise a polymer from one type of monomer (top in FIG. 8) but in other embodiments a copolymer from two types of monomer (bottom in FIG. 8). Such chain scission may be catalyzed by a photoacid generated by the EUV exposure. Similar to the crosslinking, chain scission may not substantially change the Ohnishi parameter (OP). However, the reduction in degree of polymerization reduces dry etch resistance and may benefit in the positive tonality. Example structures that undergo chain scission by the EUV exposure may include methacrylates (e.g., polymethyl mechacrylate, PMMA).

FIGS. 9A-9C illustrate example process flow diagrams of the fabrication process comprising the dry develop of the metal-free polymer film. The process flow can be followed with the figures (FIGS. 1A-1F and 4A-4E) discussed above and hence will not be described again.

In FIG. 9A, a process flow 90 starts with providing a substrate comprising an underlying layer (block 900, FIG. 1A), followed by depositing a metal-free polymer film over the underlying layer (block 910, FIG. 1B or FIG. 4A). In certain embodiments, an optional soft base may be performed (block 9i5) prior to a lithographic exposure. Next, the metal-free polymer film may be exposed to an extreme ultraviolet (EUV) irradiation through a photomask (block 920, FIG. 1C or FIG. 4B). The exposed region of the metal-free polymer film photoreacts in response to the EUV irradiation. The substrate may then be loaded into a processing chamber (block 930). In certain embodiments, an optional post-exposure bake (PEB) may be performed (block 935). A portion of the metal-free polymer film may then be selectively etched using an etch gas in the processing chamber (block 940). This process of selective etch is a part of the dry develop of the metal-free polymer film, and the portion of the metal-free polymer film to be etched may be the masked region (FIG. 1D) or the exposed region (FIG. 4C) depending on the tonality of the metal-free polymer film. After the dry develop, the underlying layer disposed under the metal-free polymer film may be patterned using the remaining portion of the metal-free polymer film as an etch mask (block 950, FIGS. 1E-1F or FIGS. 4D-4E). In certain embodiments, the process of selective etch may further comprise area selective deposition (ASD) that enhances the dry etch selectivity.

In FIG. 9B, illustrating an example of a negative photoresist, a process flow 92 starts with depositing a metal-free polymer film that comprises a carboxyl group over an underlying layer of a substrate by a spin-on process (block 912, Figure B). In certain embodiments, an optional soft base may be performed (block 915) prior to a lithographic exposure. Next, a portion of the metal-free polymer film may be decarboxylated by exposing the substrate to an EUV irradiation through a photomask (block 922, FIG. 1C). The substrate may then be loaded into a processing chamber (block 930). In certain embodiments, an optional post-exposure bake (PEB) may be performed (block 935). The masked region of the metal-free polymer film may then be selectively removed by a plasma generated in the processing chamber (block 942, FIG. 1D). After this dry develop, the underlying layer disposed under the metal-free polymer film may be patterned using the remaining portion of the metal-free polymer film (the reacted, decarboxylated region) as an etch mask (block 952, FIGS. 1E-F).

In FIG. 9C, illustrating an example of a positive photoresist, a process flow 94 starts with depositing a metal-free polymer film over an underlying layer of a substrate by a spin-on process (block 912, FIG. 4A). In certain embodiments, an optional soft base may be performed (block 915) prior to a lithographic exposure. Next, a portion of the metal-free polymer film may be oxidized by exposing the substrate to an EUV irradiation through a photomask (block 924, FIG. 4B). The substrate may then be loaded into a processing chamber (block 930). In certain embodiments, an optional post-exposure bake (PEB) may be performed (block 935). The exposed, oxidized region of the metal-free polymer film may then be selectively removed by a plasma generated in the processing chamber (block 944, FIG. 4C). After this dry develop, the underlying layer disposed under the metal-free polymer film may be patterned using the remaining portion of the metal-free polymer film (the masked, unreacted region) as an etch mask (block 954, FIGS. 4D-4E).

FIG. 10 illustrates an example plasma processing tool for dry develop in accordance with an embodiment of this disclosure.

In FIG. 10, a plasma processing system 1000 comprises a plasma processing chamber 1050 configured to sustain plasma directly above a substrate 1002 loaded onto a substrate holder 1010 to enable selective plasma etch for the dry develop of the metal-free polymer film. A process gas may be introduced to the plasma processing chamber 1050 through a gas inlet 1022 and may be pumped out of the plasma processing chamber 1050 through a gas outlet 1024. To enable using a gas mixture (e.g., CO and H₂) for the process gas and dynamically controlling the gas mixture composition during the dry develop, the gas inlet 1022 and the gas outlet 1024 may comprise a set of multiple gas inlets and gas outlets, respectively. The gas flow rates and chamber pressure may be controlled by a gas flow control system 1020 coupled to the gas inlet 1022 and the gas outlet 1024. The gas flow control system 1020 may comprise various components such as high pressure gas canisters, valves (e.g., throttle valves), pressure sensors, gas flow sensors, vacuum pumps, pipes, and electronically programmable controllers. An RF bias power source 1034 and an RF source power source 1030 may be coupled to respective electrodes of the plasma processing chamber 1050. The substrate holder 1010 may also be the electrode coupled to the RF bias power source 1034. The RF source power source 1030 is shown coupled to a helical electrode 1032 coiled around a dielectric sidewall 1016. In FIG. 10, the gas inlet 1022 is an opening in a top plate 112 and the gas outlet 1024 is an opening in a bottom plate 1014. The top plate 112 and bottom plate 1014 may be conductive and electrically connected to the system ground (a reference potential).

By selectively etching a portion of the metal-free polymer film, the dry develop generates gaseous products in the plasma processing chamber 1050. In certain embodiments, these gaseous products may be analyzed using a gas analyzer 1040. The gas analyzer 1040 may identify and quantify the gas species generated during the dry develop before they are pumped out of the plasma processing chamber 1050 through the gas outlet 1024. Based on the data obtained by the gas analyzer 1040, process conditions such as gas flow rates, process temperature, and RF power for plasma may be tuned to optimize the dry etch selectivity.

The configuration of the plasma processing system 1000 described above is by example only. In alternative embodiments, various alternative configurations may be used for the plasma processing system 1000. For example, inductively coupled plasma (ICP) may be used with RF source power coupled to a planar coil over a top dielectric cover, or capacitively coupled plasma (CCP) generated using a disc-shaped top electrode in the plasma processing chamber 1050, the gas inlet and/or the gas outlet may be coupled to the sidewall, etc. Pulsed RF power sources and pulsed DC power sources may also be used in some embodiments (as opposed to continuous wave RF power sources). Further, microwave plasma (MW) or other suitable systems may be used. In various embodiments, the RF power, chamber pressure, substrate temperature, gas flow rates and other plasma process parameters may be selected in accordance with the respective process recipe. In some embodiments, the plasma processing system 1000 may be a resonator such as a helical resonator.

In addition, embodiments of the present invention may be also applied to remote plasma systems as well as batch systems. For example, the substrate holder may be able to support a plurality of wafers that are spun around a central axis as they pass through different plasma zones.

Example embodiments are summarized here. Other embodiments can also be understood from the entirety of the specification as well as the claims filed herein.

Example 1. A method of patterning an underlying layer that includes: providing a substrate including the underlying layer; depositing a metal-free polymer film over the underlying layer; exposing the metal-free polymer film to an extreme ultraviolet (EUV) irradiation through a photomask to form an exposed region of the metal-free polymer film and a masked region of the metal-free polymer film, the exposed region photoreacting in response to the EUV irradiation; loading the substrate into a processing chamber; selectively dry etching first portions of the metal-free polymer film using an etch gas in the processing chamber to form a plurality of features including the remaining second portions of the metal-free polymer film, an etch rate of the first portions being greater than an etch rate of the second portions of the metal-free polymer film, the first portions being one of the exposed region and the masked region, the second portions being another of the exposed region and the masked region that is not the first portion, where a pitch of the plurality of features is below the feature size achievable with a 193 nm immersion lithography tool in a single patterning process; and patterning the underlying layer disposed under the metal-free polymer film using the second portion as an etch mask.

Example 2. The method of example 1, where etching the metal-free polymer film is performed using a plasma from the etch gas.

Example 3. The method of one of examples 1 or 2, where the etch gas includes H₂ and CO.

Example 4. The method of one of examples 1 to 3, where while etching the metal-free polymer film, a composition of the etch gas is changed while etching the metal-free polymer film.

Example 5. The method of one of examples 1 to 4, where while etching the metal-free polymer film, a material is selectively being deposited from the etch gas over the second portion.

Example 6. The method of one of examples 1 to 5, where the first portion is the masked region, and the second portion is the exposed region.

Example 7. The method of one of examples 1 to 6, where the photoreacting of the metal-free polymer film in response to the EUV irradiation includes reducing an Ohnishi parameter of the metal-free polymer film by at least a factor of 2.

Example 8. The method of one of examples 1 to 7, where the metal-free polymer film includes a carboxyl group, and where the photoreacting of the metal-free polymer film in response to the EUV irradiation includes decarboxylating the exposed metal free polymer film.

Example 9. The method of one of examples 1 to 8, where the photoreacting of the metal-free polymer film in response to the UV irradiation includes cyclizing the exposed metal free polymer film.

Example 10. The method of one of examples 1 to 5, where the first portion is the exposed region, and the second portion is the masked region.

Example 11. The method of example 10, where the photoreacting of the metal-free polymer film in response to the EUV irradiation includes increasing an Ohnishi parameter of the metal-free polymer film by at least a factor of 2.

Example 12. The method of one of examples 10 to 11, where the photoreacting of the metal-free polymer film in response to the UV irradiation includes adding an oxygen atom to the metal-free polymer film.

Example 13. The method of one of examples 10 to 12, where the photoreacting of the metal-free polymer film in response to the UV irradiation includes opening a ring structure of the metal-free polymer film.

Example 14. The method of one of examples 1 to 13, where the patterning is performed in the processing chamber.

Example 15. The method of one of examples 1 to 14, where the depositing is performed by a spin-on process.

Example 16. A method of patterning an underlying layer that includes: depositing a metal-free polymer film over a substrate by a spin-on process, the metal-free polymer film including a carboxyl group, the substrate including the underlying layer; decarboxylating a portion of the metal-free polymer film by exposing the substrate to an extreme ultraviolet (EUV) irradiation through a photomask, the portion of the metal-free polymer film being a region exposed to the EUV irradiation, the decarboxylating including a photoreaction in response to the EUV irradiation; loading the substrate into a processing chamber; exposing the substrate to a plasma to selectively remove a region that is masked by the photomask and not exposed to the EUV irradiation, the plasma being generated in the processing chamber, where an etch rate of the masked region is greater than an etch rate of the exposed region by at least a factor of 2; and patterning the underlying layer disposed under the metal-free polymer film using the exposed region as an etch mask.

Example 17. The method of example 16, further including cyclizing the portion of the metal-free polymer film, the cyclizing including a photoreaction in response to the EUV irradiation.

Example 18. The method of one of examples 16 or 17, where a photoreaction of the metal-free polymer film in response to the EUV irradiation increases a glass transition temperature of the metal-free polymer film.

Example 19. A method of patterning an underlying layer that includes: depositing a metal-free polymer film over a substrate including an underlying layer by a spin-on process; oxidizing a portion of the metal-free polymer film by exposing the substrate to an extreme ultraviolet (EUV) irradiation through a photomask, the oxidizing including a photoreaction in response to the EUV irradiation; loading the substrate into a processing chamber; exposing the substrate to a plasma to selectively remove the exposed region, the plasma being generated in the processing chamber, where an etch rate of the exposed region is greater than an etch rate of a region that is masked by the photomask and not exposed to the EUV irradiation by at least a factor of 2; and patterning the underlying layer disposed under the metal-free polymer film using the masked region as an etch mask.

Example 20. The method of example 19, further including opening a ring structure of the portion of the metal-free polymer film, the ring opening including a photoreaction in response to the EUV irradiation.

Example 21. The method of one of examples 1 to 15, where the metal-free polymer film includes a silane.

Example 22. The method of one of examples 1 to 15 and 21, where the metal-free polymer film includes a phosphorus.

Example 23. The method of one of examples 1 to 15 and 21 to 22, where a photoreaction of the metal-free polymer film in response to the EUV irradiation generates an acid, the acid being capable of inducing a further reaction of the metal-free polymer film.

Example 24. The method of one of examples 1 to 15 and 21 to 23, where a photoreaction of the metal-free polymer film changes a free volume of the polymer.

Example 25. The method of one of examples 1 to 15 and 21 to 24, where the metal-free polymer film includes poly(methyl methacrylate) (PMMA).

Example 26. The method of one of examples 1 to 15 and 21 to 25, where the metal-free polymer film includes a polysaccharide.

Example 27. The method of one of examples 1 to 15 and 21 to 26, further including, before the exposing of the metal-free polymer film to the EUV irradiation, performing a chemical modification to introduce a carboxyl group to the metal-free polymer film.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of patterning an underlying layer, the method comprising:
providing a substrate comprising the underlying layer,
depositing a metal-free polymer film over the underlying layer;
exposing the metal-free polymer film to an extreme ultraviolet (EUV) irradiation through a photomask to form an exposed region of the metal-free polymer film and a masked region of the metal-free polymer film, the exposed region photoreacting in response to the EUV irradiation;
loading the substrate into a processing chamber,
selectively dry etching first portions of the metal-free polymer film using an etch gas in the processing chamber to form a plurality of features comprising the remaining second portions of the metal-free polymer film, an etch rate of the first portions being greater than an etch rate of the second portions of the metal-free polymer film, the first portions being one of the exposed region and the masked region, the second portions being another of the exposed region and the masked region that is not the first portion, wherein a pitch of the plurality of features is below the feature size achievable with a 193 nm immersion lithography tool in a single patterning process; and
patterning the underlying layer disposed under the metal-free polymer film using the second portion as an etch mask.

2. The method of claim 1, wherein etching the metal-free polymer film is performed using a plasma from the etch gas.

3. The method of claim 1, wherein the etch gas comprises H₂ and CO.

4. The method of claim 1, wherein while etching the metal-free polymer film, a composition of the etch gas is changed while etching the metal-free polymer film.

5. The method of claim 1, wherein a photoreaction of the metal-free polymer film in response to the EUV irradiation generates an acid, the acid being capable of inducing a further reaction of the metal-free polymer film.

6. The method of claim 1, wherein the first portion is the masked region, and the second portion is the exposed region.

7. The method of claim 6, wherein the photoreacting of the metal-free polymer film in response to the EUV irradiation comprises reducing an Ohnishi parameter of the metal-free polymer film by at least a factor of 2.

8. The method of claim 6, wherein the metal-free polymer film comprises a carboxyl group, and wherein the photoreacting of the metal-free polymer film in response to the EUV irradiation comprises decarboxylating the exposed metal free polymer film.

9. The method of claim 6, wherein the photoreacting of the metal-free polymer film in response to the UV irradiation comprises cyclizing the exposed metal free polymer film.

10. The method of claim 1, wherein the first portion is the exposed region, and the second portion is the masked region.

11. The method of claim 10, wherein the photoreacting of the metal-free polymer film in response to the EUV irradiation comprises increasing an Ohnishi parameter of the metal-free polymer film by at least a factor of 2.

12. The method of claim 10, wherein the photoreacting of the metal-free polymer film in response to the UV irradiation comprises adding an oxygen atom to the metal-free polymer film.

13. The method of claim 10, wherein the photoreacting of the metal-free polymer film in response to the UV irradiation comprises opening a ring structure of the metal-free polymer film.

14. The method of claim 1, wherein the patterning is performed in the processing chamber.

15. The method of claim 1, wherein the depositing is performed by a spin-on process.

16. A method of patterning an underlying layer, the method comprising:
depositing a metal-free polymer film over a substrate by a spin-on process, the metal-free polymer film comprising a carboxyl group, the substrate comprising the underlying layer;
decarboxylating a portion of the metal-free polymer film by exposing the substrate to an extreme ultraviolet (EUV) irradiation through a photomask, the portion of the metal-free polymer film being a region exposed to the EUV irradiation, the decarboxylating comprising a photoreaction in response to the EUV irradiation;
loading the substrate into a processing chamber,
exposing the substrate to a plasma to selectively remove a region that is masked by the photomask and not exposed to the EUV irradiation, the plasma being generated in the processing chamber, wherein an etch rate of the masked region is greater than an etch rate of the exposed region by at least a factor of 2; and
patterning the underlying layer disposed under the metal-free polymer film using the exposed region as an etch mask.

17. The method of claim 16, further comprising cyclizing the portion of the metal-free polymer film, the cyclizing comprising a photoreaction in response to the EUV irradiation.

18. The method of claim 16, wherein the photoreaction in response to the EUV irradiation generates a photooxidant that catalyzes the decarboxylation of the portion of the metal-free polymer film.

19. A method of patterning an underlying layer, the method comprising:
depositing a metal-free polymer film over a substrate comprising an underlying layer by a spin-on process;
oxidizing a portion of the metal-free polymer film by exposing the substrate to an extreme ultraviolet (EUV) irradiation through a photomask, the oxidizing comprising a photoreaction in response to the EUV irradiation;
loading the substrate into a processing chamber,
exposing the substrate to a plasma to selectively remove the exposed region, the plasma being generated in the processing chamber, wherein an etch rate of the exposed region is greater than an etch rate of a region that is masked by the photomask and not exposed to the EUV irradiation by at least a factor of 2; and
patterning the underlying layer disposed under the metal-free polymer film using the masked region as an etch mask.

20. The method of claim 19, further comprising opening a ring structure of the portion of the metal-free polymer film, the ring opening comprising a photoreaction in response to the EUV irradiation.
